(19) United States
(12) Patent Application Publication
(10) Pub. No.: US 2017/0192577 A1
(43) Pub. Date: Jul. 6, 2017

(54) DEVICE FOR HOLDING A TOUCH-SENSITIVE SURFACE

(71) Applicant: COMMISSARIAT A L'ENERGIE ATOMIQUE ET AUX ENERGIES ALTERNATIVES, PARIS (FR)

(72) Inventors: Nicolas GUENARD, Chatou (FR); Christian BOLZMACHER, Montrouge (FR); Moustapha HAFEZ, Arcueil (FR)

(21) Appl. No.: 15/314,895

(22) PCT Filed: Jun. 9, 2015
(86) PCT No.: PCT/EP2015/062762

§ 371 Date: Nov. 29, 2016

(30) Foreign Application Priority Data
Jun. 11, 2014 (FR) 1455301

(51) Int. Cl. G06F 3/041; H03K 17/975; H03K 17/96; G06F 3/044

(52) U.S. Cl. CPC G06F 3/0414; G06F 3/044; H03K 17/975; H03K 17/962

(57) ABSTRACT

A device for holding a touch-sensitive surface in a frame comprises deformable means arranged between the upper rim of the frame and the upper face of the surface, and capacitive means arranged between the lower rim of the frame and the opposite face of the surface to detect a displacement of the surface. The deformable means and the capacitive means are arranged on the perimeter of the frame so as to hold the surface in the frame.

### FIELD OF THE INVENTION

The invention lies in the field of touch-sensitive surfaces and relates more particularly to a device for holding such a surface.

### STATE OF THE ART

There are different approaches for making a surface of any kind touch-sensitive, by making it possible to locate a press on the surface. The known solutions are mainly to spread a capacitive film over the surface, to place an infrared frame on the surface or to measure force using strain gauges or pressure sensors. These solutions are particularly suited to surfaces said to be of small size, generally less than thirty or so inches, such as tablets for example. However, they become inappropriate for larger surfaces to be touch-sensitized, such as, for example, glass plates for tables or car dome lights.

In effect, the transition to larger surfaces generates problems linked to the rigidity and therefore the deformation of the surface under the application of an interaction force. Even though satisfactory solutions are proposed to approach this aspect of deformation of a surface, drawbacks remain, including, among others, that of the difficulty of having a good hold of the surface because of the larger dimensions.

Most of the existing devices for holding touch-sensitive surfaces generally use an elastic element making it possible to press the surface to be made touch-sensitive against the force sensor. The latter is then situated between the surface and a frame. Such devices are for example described in the patents U.S. Pat. No. 7,109,976 or U.S. 7,149,571.

Another device described in the application EP0497398 A2, makes it possible to hold a vertical or horizontal plate by suspension means on the top part of the plate and elastic elements on the bottom part. With the purpose of the holding device being only to relieve the weight of the plate, strain gauges linked to mounting elements then make it possible to measure the forces generated by the interaction.

The abovementioned patent U.S. Pat. No. 7,109,976 describes an attachment device for a display screen which comprises a base having first and second surfaces, and a part extending from the second surface. The base is configured to be mounted on the screen and to be positioned between the screen and a structure that remains adjacent to the screen, for example a bezel or a frame of the screen. Even though this arrangement prevents certain foreign bodies from passing between the screen and the adjacent structure, dust and liquids can stagnate in the duly formed cup. Moreover, a prestressing adding to the weight of the surface is applied by an elastic element to the force sensor and modifies the range of operation of the sensor to the detriment of the sensitivity thereof.

Thus, in the prior art, there is no solution to mitigate the drawbacks of the existing approaches, and which is suitable for holding a surface of large size to be touch-sensitized. The present invention addresses this need.

### SUMMARY OF THE INVENTION

One object of the present invention is to provide a device for holding a touch-sensitive surface of large size, in order to avoid the deformations of the surface.

Advantageously, the device of the invention makes it possible to hold a surface at several points to increase the apparent rigidity of the surface and avoid the indentation thereof in interaction.

Another object of the present invention is to propose a modular fixing device for a touch-sensitive surface of large size that makes it possible to easily add or remove fixing modules.

Advantageously, the device of the invention makes it possible to limit the deformation of the surface to be touch-sensitized by fixing it to a built-in frame.

Another object of the present invention is to provide a fixing device for a surface to be touch-sensitized that offers easy implementation and a reduced implementation cost.

Another object of the invention is to provide a device which combines the functions of holding a surface to be touch-sensitized with those of detecting an interaction on the surface. In one embodiment, the device of the invention can be coupled to an electronic module in order to perform capacitive measurements, and be associated with an interaction locating method making it possible to determine a point of interaction on the surface.

The present invention will apply advantageously to interactive terminals of large size, furniture to be touch-sensitized, or even any so-called “single touch” application.

Because of the low cost of the proposed device, a typical application will be to the touch-sensitization of a dome light of large size in the interior of a motor vehicle. Advantageously, the proposed device does not affect the transparency of the dome light, and is particularly well suited to allowing the light to pass through.

To obtain the results sought, the invention proposes a device for holding a surface of large size to be touch-sensitized comprising:

a monolithic frame, having an upper rim and a lower rim, for embedding the surface of large size to be touch-sensitized, the surface having an upper face and an opposite face;

deformable means arranged between the upper rim of the frame and the upper face of the surface; and

capacitive means arranged between the lower rim of the frame and the opposite face of the surface making it possible to detect a displacement of said surface;

characterized in that the deformable means and the capacitive means are arranged on the perimeter of the monolithic frame so as to hold the surface in the frame.

In one embodiment, the deformable means are arranged facing the capacitive means. Advantageously, the deformable means can be arranged partially overlapping the capacitive means.

According to implementations, the deformable means are of rigid or semi-rigid material.

In an advantageous variant, the deformable means are capacitive sensors. The capacitive sensors can be coupled to the capacitive means arranged between the lower rim of the frame and the opposite face of the surface to cooperate in the detection of an interaction on the surface.

In a variant, a capacitive sensor comprises a first electrode secured to the surface and a second electrode separated from the first by a dielectric and secured to the frame.

In one embodiment, the device of the invention comprises at least one seal which extends between the surface and the lower rim of the frame.

An advantageous embodiment of the device of the invention is for a vehicle dome light.

In one embodiment, the device of the invention comprises at least three deformable upper elements and three capacitive sensors.

### DESCRIPTION OF THE FIGURES

Different aspects and advantages of the invention will emerge supporting the description of a preferred but nonlimiting mode of implementation of the invention, with reference to the figures below:

FIG. 1 shows, in side view, a theoretical diagram of the holding device of the invention in an embodiment;

FIG. 2 shows, in side view, a variant implementation of the holding device of FIG. 1;

FIGS. 3a to 3b show variants of arrangement of the holding device of the invention;

FIGS. 4a to 4c show 3D views of a monolithic frame according to variant implementations of the holding device of the invention.

### DETAILED DESCRIPTION OF THE INVENTION

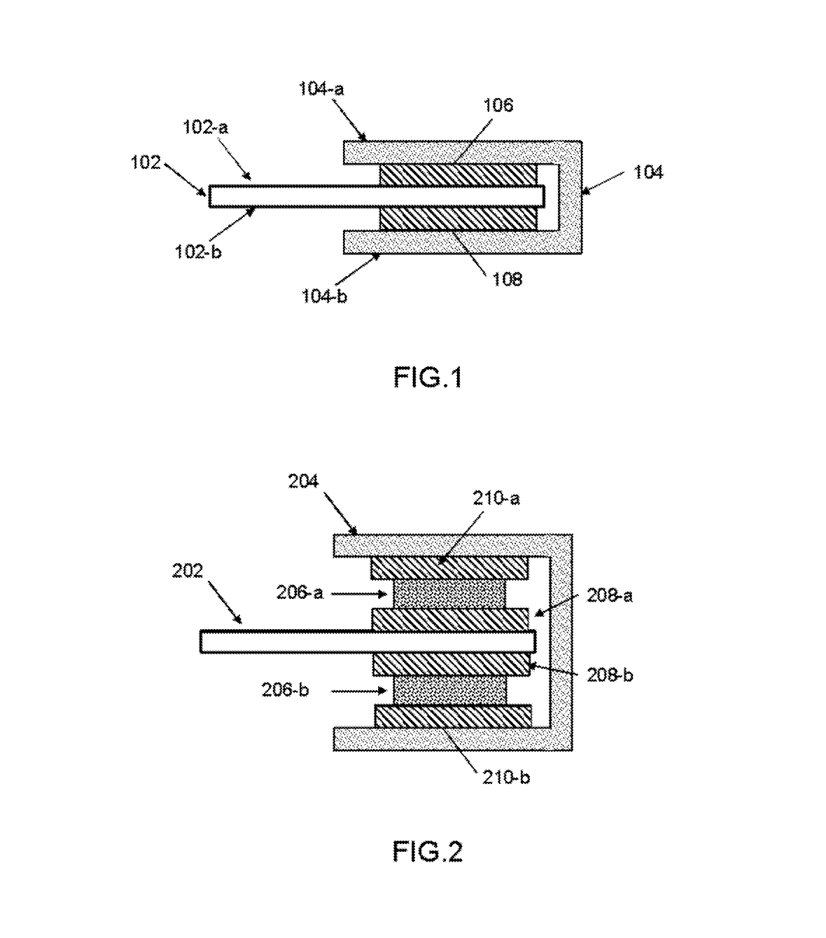

FIG. 1 shows, in side view, a theoretical diagram of the holding device of the invention in an embodiment.

Generally, the device of the invention makes it possible to hold a plate (102) to be touch-sensitized in a frame (104). The frame has an upper rim (104-a) and a lower rim (104-b). The plate (102) has an upper face (102-a) and an opposite face (102-b). The device for holding the plate comprises a first upper element (106) which extends between the upper face (102-a) of the plate and the upper rim (104-a) of the frame. The device further comprises a second lower element (108) which extends between the opposite face (102-b) of the plate and the lower rim (104-b) of the frame. The lower element is a capacitive component which makes it possible to detect a displacement of the plate in an interaction therewith, like a single touch on the surface. Preferentially, the capacitive component comprises a first mobile electrode secured to the opposite face of the touch-sensitive surface (102-b) and a second electrode securely fixed to the frame (104-b).

Advantageously, the holding device of the invention makes it possible for a plate to be retained between the upper and lower rims of the frame by an arrangement and a distribution of elastic upper elements and of capacitive lower elements. The plate is then clamped by the device which ensures that it is held.

The upper element (106) is an elastic element which can be made from different rigid or semi-rigid materials such as, for example, polymers or foam or a spring in order to allow a sufficient deformation upon an interaction on the surface of the plate, and a reversion to their to their initial form at rest.

The deformable elastic upper element used in the invention can be of different forms and configurations. In one embodiment as illustrated in FIG. 1, it is of a form substantially identical to the capacitive lower element and is placed facing the latter (108).

In practice, each elastic upper element can be glued to the frame and to the surface to be touch-sensitized.

Similarly, the upper element can have a thickness at rest that is variable, and which is identical to or different from the thickness of the capacitive lower element.

A person skilled in the art will understand that the examples described are not limiting and that the device of the invention can comprise elastic and capacitive elements in equal or different numbers depending on the size or the form of the surface to be touch-sensitized or depending on the application. In a preferential implementation, there are at least three elastic means and there are at least three capacitive means. For example, in an application for a vehicle dome light, the glass of the dome light will be able to be retained in the frame by four devices positioned at each corner of the surface.

FIG. 2 shows, in side view, a variant implementation of the holding device of the invention in which the deformable element consists of a capacitive element. The holding device in this variant consists of two capacitive sensors joined to form a unitary capacitive device, called fork sensor. The fork sensor comprises a central armature (208-a, 208-b) secured to the surface 202, and two outer armatures (210-a, 210-b) secured to the rims of the frame, the outer armatures being respectively separated from the central armature by a dielectric material (206-a, 206-b).

The capacitive sensors are situated respectively on either side of the plate 202 having an upper face and a lower face. In the context of the invention, the sensor situated above the plate is called ‘upper sensor’ and the sensor situated below the plate is called ‘lower sensor’. In one implementation, the sensors are arranged on the edges of the plate and embedded in a frame 204. Thus, advantageously, the fork sensor makes it possible to hold the surface 202 with no additional fixing system.

To make it possible to detect a displacement of the plate upon an interaction on the surface, each sensor comprises two electrodes separated by a dielectric (206-a, 206-b). The upper sensor comprises a first electrode 208-a secured to the plate and a second electrode 210-a secured to the frame. A dielectric 206-a consisting of an elastic and insulating material, such as silicone or polyurethane for example, is situated between the two electrodes. The dielectric makes it possible to increase the measured capacitance by increasing the permittivity of the medium. Also, it constitutes a return function which is compressed when a force linked to an interaction is applied to the surface to bring the two electrodes closer together, and which is relaxed when the force disappears in order to return the electrodes to their initial position.

Similarly, the lower sensor comprises a first electrode 208-b secured to the plate and a second electrode 210-b secured to the frame, separated by a dielectric 206-b.

Each electrode secured to the plate is mobile under the effect of a pressure on the plate and deformation of the dielectric. Each electrode secured to the frame is fixed and constitutes a signal electrode which makes it possible to measure forces exerted on the surface. The fork sensor-based holding device of the invention can be coupled to an interaction detection and locating system such as that described in the patent application by the applicant entitled “Method and device for locating an interaction on a touch-sensitive surface” filed the same day.

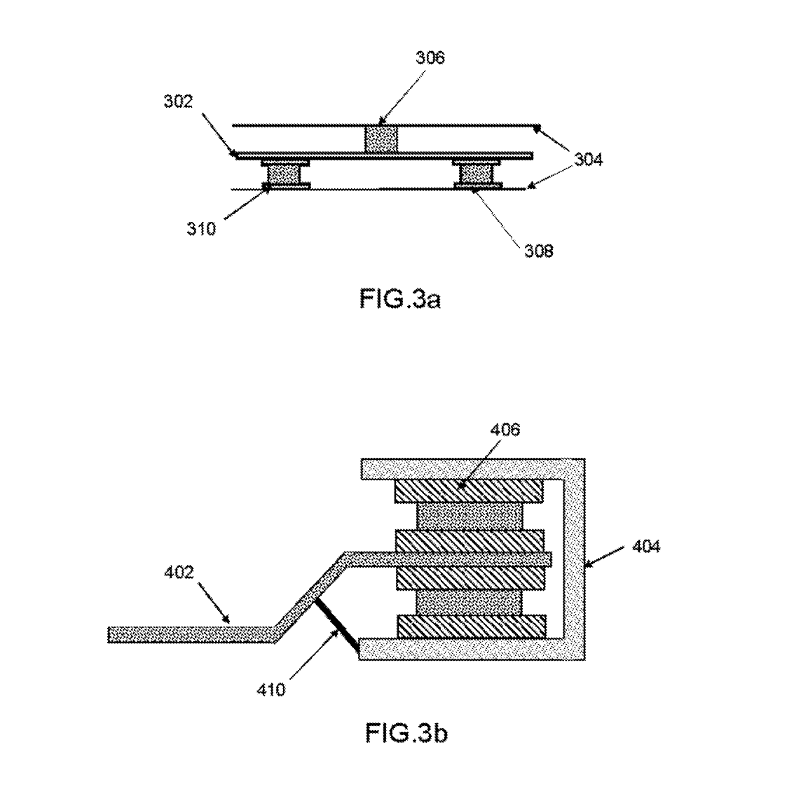

FIGS. 3a and 3b show variant arrangements of the holding device of the invention.

FIG. 3a is a side view which illustrates an exemplary embodiment of the holding device where the deformable upper element (306) is not directly facing a capacitive element (308). In the configuration of FIG. 3a, the deformable upper element is positioned equidistantly between two capacitive elements (308, 310). Advantageously, a deformable upper element can be arranged so as to be totally or partially facing a capacitive lower element.

According to the variant implementations, the deformable upper element can be a capacitive element as described with reference to FIG. 2.

FIG. 3b illustrates a variant implementation of the holding device of the invention, in which a seal (410) is added between the plate (402) and the lower rim of the frame (404) to avoid a cup aspect which can be produced on some surfaces of large size. The role of the seal is then to ensure the seal-tightness of the system to dust and to liquids. It consists of an impervious material, such as a polymer or a plastic film for example, and is deformable in order to disrupt as little as possible the deformation of the capacitive sensors. The latter is glued both to the frame (404) and to the plate (402). In this variant, the deformable upper element (406) can be an elastic element or a capacitive element.

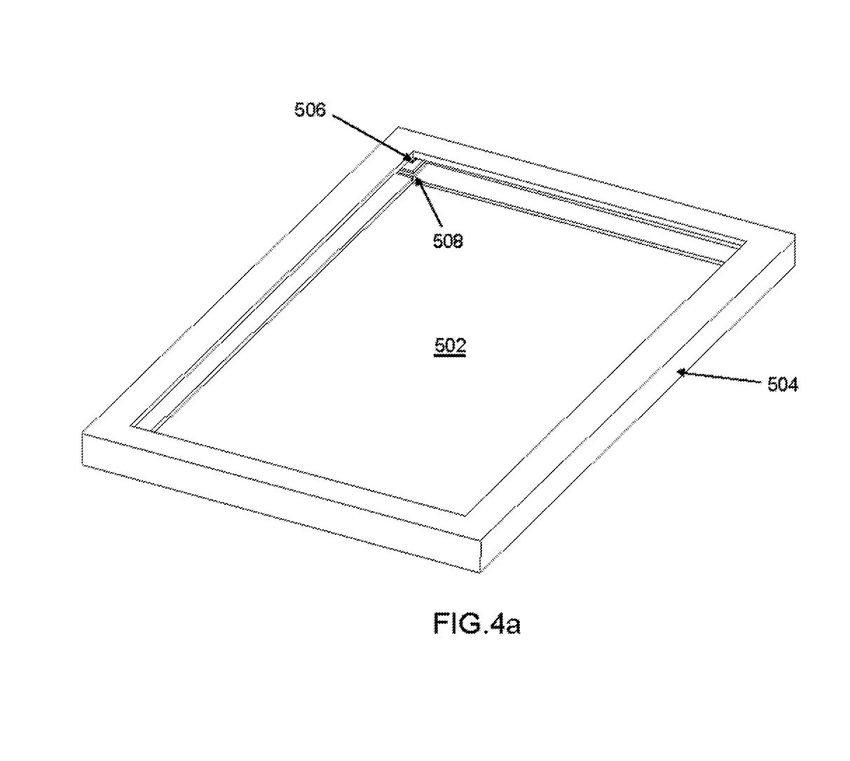

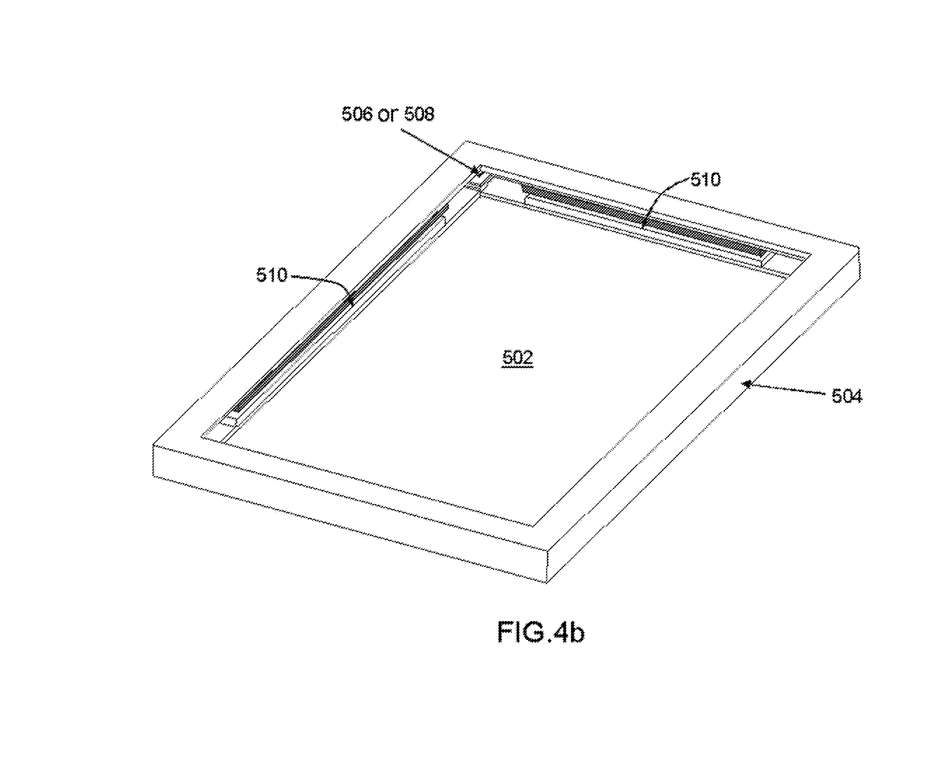

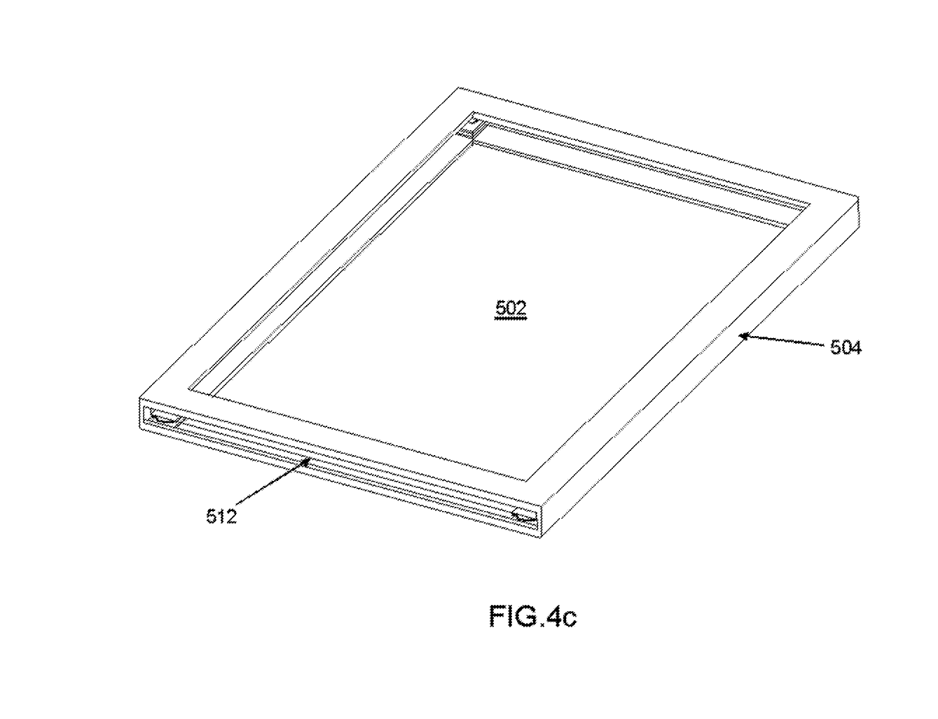

FIGS. 4a and 4b illustrate a frame in a 3D representation, that makes it possible to insert a surface (502) to be touch-sensitized of large size. In a preferential implementation, the frame is a monolithic or unitary block (504), forming a single piece in which the surface is embedded. The surface can be held according to the variants described with reference to FIGS. 1 to 3, either by pairs of fork sensors (506, 508), or by upper (506) or lower (508) sensors and deformable elements (510) placed respectively on the opposite face of the surface. As described previously, the number of sensors can vary from at least three sensors to a plurality distributed over the perimeter of the frame. The number and the position of the sensors and of the deformable fixing elements can vary depending on the size and the rigidity of the surface. In a preferential implementation, the surface is held by four pairs of fork sensors positioned at each corner of the frame.

FIG. 4c illustrates a variant monolithic frame having a lateral opening (512) making it possible to slide the surface into the frame.

According to other variants, the frame can comprise a removable part (not shown) which can be screwed or glued to the frame after the insertion of the surface to close the frame and provide additional protection.

More generally, the frame is a rigid structure which can be made from different rigid or semi-rigid materials such as, for example, metals (steel, aluminum, etc.) and plastics (ABS, PC, etc.) in order to have a sufficient strength upon an interaction on the surface of the plate.

A person skilled in the art will understand that only a few examples are described but are in no way limiting on the possibilities of arrangement between the deformable upper elements and the capacitive lower elements. Thus, advantageously, depending on the size of the surface to be touch-sensitized, fixing modules can easily be added or removed. In a variant, one and the same surface can be held in a frame by modules.

1. A device for holding a surface of large size to be touch-sensitized comprising:
a monolithic frame, having an upper rim and a lower rim, for embedding the surface of large size to be touch-sensitized, the surface having an upper face and an opposite face;
deformable means arranged between the upper rim of the frame and the upper face of the surface; and
capacitive means arranged between the lower rim of the frame and the opposite face of the surface making it possible to detect a displacement of said surface;
wherein the deformable means and the capacitive means are arranged on the perimeter of the monolithic frame so as to hold the surface in said frame.

2. The device as claimed in claim 1, wherein the deformable means are arranged facing the capacitive means.

3. The device as claimed in claim 1, wherein the deformable means are arranged partially overlapping the capacitive means.

4. The device as claimed in claim 1, wherein the deformable means are of rigid or semi-rigid material.

5. The device as claimed in claim 1, wherein the deformable means are capacitive sensors.

6. The device as claimed in claim 5, wherein the capacitive sensors are coupled to the capacitive means arranged between the lower rim of the frame and the opposite face of the surface to cooperate in the detection of an interaction on the surface.

7. The device as claimed in claim 6, wherein a capacitive sensor comprises a first electrode secured to the surface and a second electrode separated from the first by a dielectric and secured to the frame.

8. The device as claimed in claim 1, comprising at least one seal which extends between the surface and the lower rim of the frame.

9. The device as claimed in claim 1, wherein the surface is a vehicle dome light.

10. The device as claimed in claim 1, wherein there are least three of the deformable means and there are at least three of the capacitive means.
